(19) United States
(12) Patent Application Publication
(10) Pub. No.: US 2025/0287757 A1
(43) Pub. Date: Sep. 11, 2025

(54) DISPLAY DEVICE, METHOD OF MANUFACTURING THE SAME, AND AN ELECTRONIC DEVICE INCLUDING THE DISPLAY DEVICE

(71) Applicant: Samsung Display Co., LTD., Yongin-si (KR)

(72) Inventors: JAESIK KIM, Yongin-si (KR); WOO YONG SUNG, Yongin-si (KR)

(21) Appl. No.: 19/052,610

(22) Filed: Feb. 13, 2025

(30) Foreign Application Priority Data
Mar. 8, 2024 (KR) 10-2024-0032975

(51) Int. Cl. H10H 29/855; H10H 29/01

(52) U.S. Cl. CPC H10H 29/855; H10H 29/012; H10H 29/0363

(57) ABSTRACT

A display device includes a light emitting diode disposed on a thin-film transistor (TFT) array substrate, a micro lens disposed on the light emitting diode, overlapping the light emitting diode, and including a resin, and a hydrophobic coating layer disposed on the micro lens and covering the micro lens.

This application claims priority to Korean Patent Application No. 10-2024-0032975, filed on Mar. 8, 2024, and all the benefits accruing therefrom under 35 U.S.C. § 119, the content of which in its entirety is herein incorporated by reference.

### BACKGROUND

### (1) Field

Implementations of the invention relate generally to a display device, a method of manufacturing the display device, and an electronic device including the display device.

### (2) Description of The Related Art

A light emitting diode (LED) is an element that converts electrical signals into light forms such as infrared and visible light by using the characteristics of compound semiconductors. In particular, a light emitting diode is a semiconductor element that injects holes and electrons when a forward voltage is applied to the P-N diode, and converts the energy generated by recombination of holes and electrons into light energy.

### SUMMARY

Embodiments provide a display device.

Embodiments provide a method of manufacturing the display device.

Embodiments provide an electronic device including the display device.

A display device according to an embodiment includes a light emitting diode disposed on a thin-film transistor (TFT) array substrate, a micro lens disposed on the light emitting diode, overlapping the light emitting diode, and including a resin, and a hydrophobic coating layer disposed on the micro lens and covering the micro lens.

In an embodiment, a contact angle of the hydrophobic coating layer with respect to water may be in a range of about 100° to about 200°, and a contact angle of the hydrophobic coating layer with respect to the resin may be in a range of about 20° to about 100°.

In an embodiment, the display device may further include an adhesive layer disposed between the micro lens and the hydrophobic coating layer.

In an embodiment, the display device may further include a functional layer disposed between the micro lens and the hydrophobic coating layer.

In an embodiment, the functional layer may include an organic material.

In an embodiment, the functional layer may include at least one of an inorganic oxide and a metal oxide.

In an embodiment, the display device may further include a hydrophobic pinning layer disposed between the light emitting diode and the micro lens.

In an embodiment, a boundary of the hydrophobic pinning layer may be aligned with a boundary of the micro lens in a plan view.

In an embodiment, the light emitting diode may include a first semiconductor layer, an active layer disposed on the first semiconductor layer, and a second semiconductor layer disposed on the active layer.

In an embodiment, the display device may further include a pixel electrode disposed under the light emitting diode, and a common electrode disposed on the light emitting diode. In such an embodiment, the light emitting diode may be arranged perpendicularly to the pixel electrode.

A method of manufacturing a display device according to an embodiment includes forming a light emitting diode package including a light emitting diode, and transferring the light emitting diode package onto a TFT array substrate. In such an embodiment, the forming the light emitting diode package includes forming a micro lens on the light emitting diode, where the micro lens overlaps the light emitting diode and includes a resin, and forming a hydrophobic coating layer on the micro lens, where the hydrophobic coating layer covers the micro lens.

In an embodiment, the forming the light emitting diode package may further include forming an adhesive layer between the micro lens and the hydrophobic coating layer.

In an embodiment, the forming the light emitting diode package may further include forming a functional layer between the micro lens and the hydrophobic coating layer.

In an embodiment, the forming the light emitting diode package may further include forming a hydrophobic pinning layer between the micro lens and the hydrophobic coating layer.

In an embodiment, the forming the hydrophobic pinning layer may include forming a preliminary hydrophobic pinning layer, and removing a portion of the preliminary hydrophobic pinning layer in a way such that a boundary of the preliminary hydrophobic pinning layer is aligned with a boundary of the micro lens in a plan view.

In an embodiment, the light emitting diode package may be transferred through a fluidic self-assembly (FSA) process.

An electronic device according to an embodiment includes a display device and a power supply configured to provide power to the display device. The display device includes a light emitting diode disposed on a thin-film transistor (TFT) array substrate, a micro lens disposed on the light emitting diode, overlapping the light emitting diode, and including a resin, and a hydrophobic coating layer disposed on the micro lens and covering the micro lens.

Therefore, a display device according to embodiments of the invention may be formed by transferring a light emitting diode package onto a TFT array substrate. In such embodiments, the light emitting diode package may be transferred through a fluidic self-assembly (FSA) process. For example, the light emitting diode package may be aligned on the TFT array substrate by electric/magnetic fields in a fluid.

In such embodiments, the light emitting diode package may include a micro lens and a functional layer, and a hydrophobic coating layer. The micro lens may include or be formed of resin, the functional layer may cover the micro lens, and the hydrophobic coating layer may reduce the surface friction coefficient.

Accordingly, in such embodiments, while the light emitting diode package is transferred through the FSA process, fluid may not penetrate into the interior of the light emitting diode package, the micro lens may be protected, and the light emitting diode package may be smoothly aligned to the target position.

### BRIEF DESCRIPTION OF THE DRAWINGS

The accompanying drawings, which are included to provide a further understanding of the invention and are incorporated in and constitute a part of this specification, illustrate embodiments of the invention together with the description.

FIG. 1 is a plan view illustrating a display device according to an embodiment of the invention.

FIG. 2 is an enlarged view of area A of FIG. 1.

FIG. 3 is a cross-sectional view taken along line I-I′ of FIG. 2.

FIG. 4 is an enlarged view of area B of FIG. 3.

FIG. 5 is an enlarged view of area C of FIG. 4.

FIGS. 6 to 13 are cross-sectional views illustrating an embodiment of a method of manufacturing the display device of FIG. 1.

FIG. 14 is a block diagram illustrating an electronic device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below. “About” or “approximately” as used herein is inclusive of the stated value and

means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, embodiments of the invention will be described in detail with reference to the accompanying drawings.

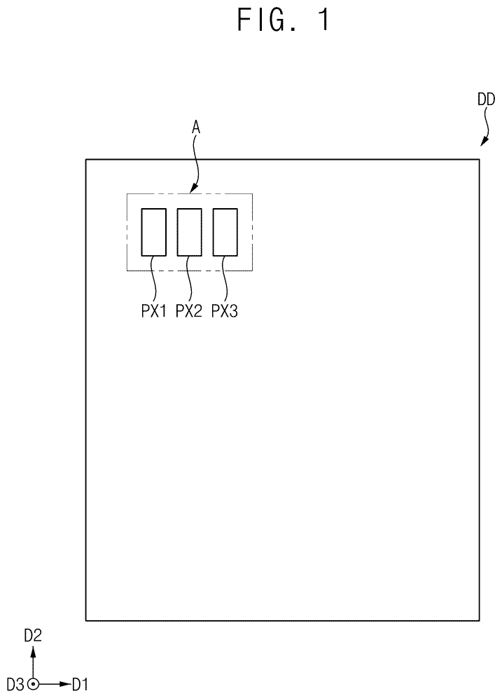

FIG. 1 is a plan view illustrating a display device according to an embodiment of the invention.

Referring to FIG. 1, a display device DD according to an embodiment of the invention may include at least one pixel. In an embodiment, pixels may be arranged in the display device DD in a predetermined form, e.g., a matrix form. In an embodiment, the pixels may be arranged in the display device in a first direction D1 and a second direction D2 crossing the first direction D1 in a plan view or when viewed in a third direction D3. Here, the third direction D3 may be a direction perpendicular to a plane defined by the first direction D1 and the second direction D2. The third direction D3 may be a thickness direction of the display device DD. In an embodiment, for example, the display device DD may include a first pixel PX1, a second pixel PX2, and a third pixel PX3. Each of the first to third pixels PX1, PX2, and PX3 may emit light having a certain color, and an image may be displayed by combining the lights emitted from the first to third pixels PX1, PX2, and PX3.

In an embodiment, the display device DD may be a micro light emitting diode (LED) display device.

However, the invention is not limited thereto, and an embodiment of the display device DD may be one of other types of display device. In an embodiment, for example, the display device DD may be an organic light emitting diode display device (OLED), an inorganic light emitting diode display device (inorganic EL), a quantum dot light emitting diode display device (QED), a nano LED display device, a plasma display device (PDP), a field emission display (FED), a cathode ray display (CRT), a liquid crystal display (LCD), or an electrophoretic display (EPD).

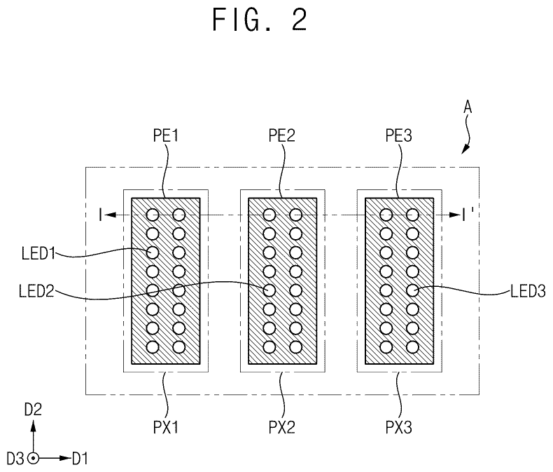

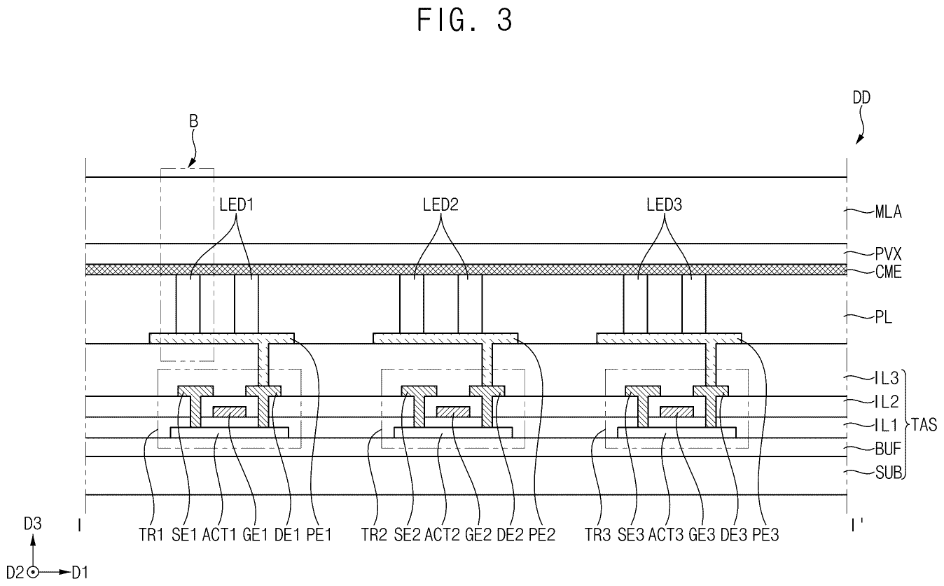

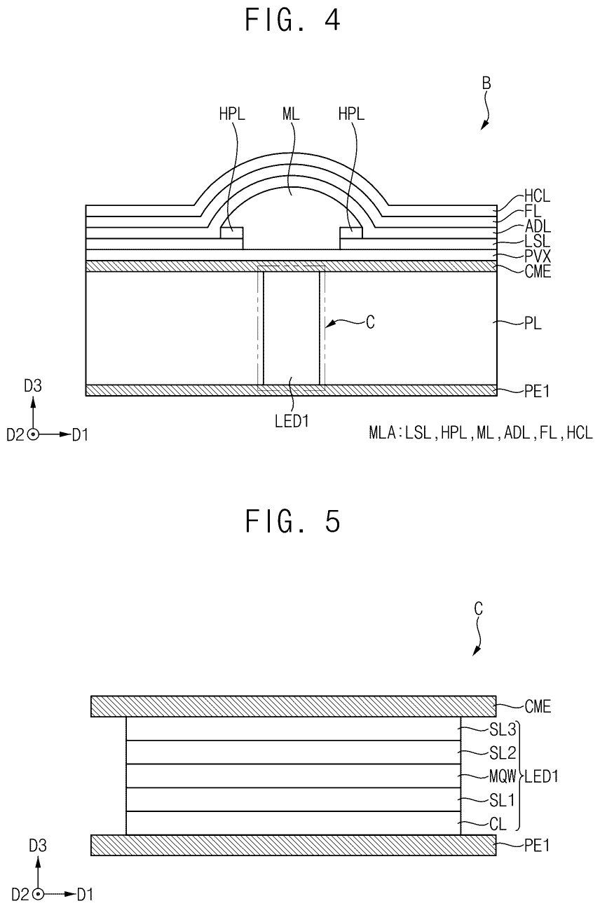

FIG. 2 is an enlarged view of area A of FIG. 1. FIG. 3 is a cross-sectional view taken along line I-I′ of FIG. 2. FIG. 4 is an enlarged view of area B of FIG. 3. FIG. 5 is an enlarged view of area C of FIG. 4.

Referring to FIGS. 2 and 3, in an embodiment, the display device DD may include a thin-film transistor (TFT) array substrate TAS, a first light emitting diode LED1, a second light emitting diode LED2, a third light emitting diode LED3, a planarization layer PL, a common electrode CME, a passivation layer PVX, and a micro lens array MLA.

The TFT array substrate TAS may include a substrate SUB, a buffer layer BUF, a first transistor TR1, a second transistor TR2, a third transistor TR3, a first insulating layer IL1, and a second insulating layer IL2, a third insulating layer IL3, a first pixel electrode PE1, a second pixel electrode PE2, and a third pixel electrode PE3.

The first transistor TR1 may include a first active pattern ACT1, a first gate electrode GE1, a first source electrode SE1, and a first drain electrode DE1. The second transistor TR2 may include a second active pattern ACT2, a second gate electrode GE2, a second source electrode SE2, and a second drain electrode DE2. The third transistor TR3 may include a third active pattern ACT3, a third gate electrode GE3, a third source electrode SE3, and a third drain electrode DE3.

The substrate SUB may include a transparent material or an opaque material. The substrate SUB may be made of or defined by a transparent resin substrate. Examples of the transparent resin substrate may include a polyimide substrate. In this case, the substrate SUB may include a first organic layer, a first barrier layer, a second organic layer, etc. In an embodiment, the substrate SUB may include a quartz substrate, a synthetic quartz substrate, a calcium fluoride substrate, a F-doped quartz substrate, a soda-lime glass substrate, a non-alkali glass substrate, etc. These can be used alone or in combination with each other.

The buffer layer BUF may be disposed on the substrate SUB. The buffer layer BUF may effectively prevent metal atoms or impurities from diffusing from the substrate SUB to the first to third transistors TR1, TR2, and TR3. In addition, the buffer layer BUF may improve the flatness of the surface of the substrate SUB when the surface of the substrate SUB is not uniform. In an embodiment, for example, the buffer layer BUF may include an inorganic material such as silicon oxide, silicon nitride, silicon oxynitride, etc. These can be used alone or in combination.

The first to third active patterns ACT1, ACT2, and ACT3 may be disposed on the buffer layer BUF. Each of the first to third active patterns ACT1, ACT2, and ACT3 may include a metal oxide semiconductor, an inorganic semiconductor (e.g., amorphous silicon, poly silicon), or an organic semiconductor.

The metal oxide semiconductors may include a binary compound (ABx), a ternary compound (ABxCy), a four-component compound (ABxCyDz), etc. including indium (In), zinc (Zn), gallium (Ga), tin (Sn), titanium (Ti), aluminum (Al), hafnium (Hf), zirconium (Zr), magnesium (Mg), etc. In an embodiment, For example, the metal oxide semiconductor may include zinc oxide (ZnOx), gallium oxide (GaOx), tin oxide (SnOx), indium oxide (InOx), indium gallium oxide (IGO), indium zinc oxide (IZO), indium tin oxide (ITO), indium zinc tin oxide (IZTO), indium gallium zinc oxide (IGZO), etc. These can be used alone or in combination with each other.

The first insulating layer IL1 may be disposed on the buffer layer BUF. The first insulating layer IL1 may cover the first to third active patterns ACT1, ACT2, and ACT3, and may be formed along the profile of the first to third active patterns ACT1, ACT2, and ACT3. In an embodiment, for example, the first insulating layer IL1 may include an inorganic material such as silicon oxide (SiOx), silicon nitride (SiNx), silicon carbide (SiCx), silicon oxynitride (SiOxNy), or silicon oxycarbide (SiOxCy). These can be used alone or in combination with each other.

The first to third gate electrodes GE1, GE2, and GE3 may be disposed on the first insulating layer IL1. The first gate electrode GE1 may overlap the first active pattern ACT1, the second gate electrode GE2 may overlap the second active pattern ACT2, and the third gate electrode GE3 may overlap the third active pattern ACT3.

Each of the first to third gate electrodes GE1, GE2, and GE3 may include metal, alloy metal nitride, conductive metal oxide, transparent conductive material, etc. Examples of the metal may include silver (Ag), molybdenum (Mo), aluminum (Al), tungsten (W), copper (Cu), nickel (Ni), chromium (Cr), titanium (Ti), and tantalum (Ta), platinum (Pt), scandium (Sc), etc. Examples of the conductive metal oxide include indium tin oxide and indium zinc oxide. In addition, examples of the metal nitride may include aluminum nitride (AINx), tungsten nitride (WNx), and chromium nitride (CrNx). These can be used individually or in combination with each other.

The second insulating layer IL2 may be disposed on the first insulating layer IL1. The second insulating layer IL2 may cover the first to third gate electrodes GE1, GE2, and GE3, and may be formed along the profile of each of the first to third gate electrodes GE1, GE2, and GE3. In an embodiment, for example, the second insulating layer IL2 may include an inorganic material such as silicon oxide, silicon nitride, silicon carbide, silicon oxynitride, or silicon oxycarbide. These can be used alone or in combination with each other.

The first to third source electrodes SE1, SE2, and SE3 may be disposed on the second insulating layer IL2. The first source electrode SE1 may contact the first active pattern ACT1 through a contact hole defined in the first and second insulating layers IL1 and IL2. The second source electrode SE2 may contact the second active pattern ACT2 through a contact hole defined in the first and second insulating layers IL1 and IL2. The third source electrode SE3 may contact the third active pattern ACT3 through a contact hole defined in the first and second insulating layers IL1 and IL2.

The first to third drain electrodes DE1, DE2, and DE3 may be disposed on the second insulating layer IL2. The first drain electrode DE1 may contact the first active pattern ACT1 through a contact hole defined in the first and second insulating layers IL1 and IL2. The second drain electrode DE2 may contact the second active pattern ACT2 through a contact hole defined in the first and second insulating layers IL1 and IL2. The third drain electrode DE3 may contact the third active pattern ACT3 through a contact hole defined in the first and second insulating layers IL1 and IL2.

In an embodiment, for example, each of the first to third source electrodes SE1, SE2, and SE3 may include metal, alloy, metal nitride, conductive metal oxide, transparent conductive material, etc. These can be used alone or in combination with each other.

The first to third drain electrodes DE1, DE2, and DE3 may include a same material as the first to third source electrodes SE1, SE2, and SE3.

The third insulating layer IL3 may be disposed on the second insulating layer IL2. The third insulating layer IL3 may cover the first to third source electrodes SE1, SE2, and SE3 and the first to third drain electrodes DE1, DE2, and DE3. The third insulating layer IL3 may include an organic material. In an embodiment, for example, the third insulating layer IL3 may include an organic material such as phenolic resin, polyacrylates resin, polyimides rein, polyamides resin, siloxane resin, and epoxy resin, etc. These can be used alone or in combination with each other.

The first to third pixel electrodes PE1, PE2, and PE3 may be disposed on the third insulating layer IL3. The first pixel electrode PE1 may contact the first drain electrode DE1 (or the first source electrode SE1) through a contact hole defined in the third insulating layer IL3, the pixel electrode PE2 may contact the second drain electrode DE2 (or the second source electrode SE2) through a contact hole defined in the third insulating layer IL3, and the third pixel electrode PE3 may contact the third drain electrode DE3 (or the third source electrode SE3) through a contact hole defined in the third insulating layer IL3.

In an embodiment, for example, each of the first to third pixel electrodes PE1, PE2, and PE3 may include metal, alloy, metal nitride, conductive metal oxide, transparent conductive material, etc. These can be used alone or in combination with each other.

In an embodiment where each of the first to third pixel electrodes PE1, PE2, and PE3 is bonded to each of the first to third light emitting diodes LED1, LED2, and LED3, it is desirable to lower the sheet resistance of the first to third pixel electrodes PE1, PE2, and PE3. In an embodiment, for example, each of the first to third pixel electrodes PE1, PE2, and PE3 may have a two-layer structure including titanium (Ti)/copper (Cu). However, embodiments of the invention are not limited thereto.

The first light emitting diode LED1 may be disposed on the first pixel electrode PE1, the second light emitting diode LED2 may be disposed on the second pixel electrode PE2, and the third light emitting diode LED3 may be disposed on the third pixel electrode PE3. In an embodiment, as shown in FIG. 2, a plurality of first light emitting diodes may be disposed on the first pixel electrode PE1 in a predetermined arrangement, and a plurality of second light emitting diodes may be disposed on the second pixel electrode PE2 in a predetermined arrangement, and a plurality of third light emitting diodes may be disposed on the third pixel electrode PE3 in a predetermined arrangement, in a plan view or when viewed in the third direction D3.

In an embodiment, as shown in FIG. 3, the first light emitting diode LED1 may be arranged perpendicularly to the first pixel electrode PE1, the second light emitting diode LED2 may be arranged perpendicularly to the electrode PE2, and the third light emitting diode LED3 may be arranged perpendicularly to the third pixel electrode PE3. In an embodiment, a height (i.e., a length in the third direction D3) of each of the first light emitting diode LED1, the second light emitting diode LED2 and the third light emitting diode LED3 may be greater than a width or length (i.e., a length in the first direction D1 or the second direction D2) thereof. In an embodiment, where each of the first light emitting diode LED1, the second light emitting diode LED2 and the third light emitting diode LED3 has a stacked structure of a plurality of layers, the layer may be stacked in the third direction D3.

In an embodiment, each of the first to third light emitting diodes LED1, LED2, and LED3 may be a micro light emitting diode.

The planarization layer PL may be disposed on the third insulating layer IL3. The planarization layer PL may be arranged to surround or cover the first light emitting diode LED1, the second light emitting diode LED2, and the third light emitting diode LED3. The planarization layer PL may flatten the steps caused by the first light emitting diode LED1, the second light emitting diode LED2, and the third light emitting diode LED3. In an embodiment, for example, the top surface of the planarization layer PL may be positioned at a same level as the top surfaces of the first to third light emitting diodes LED1, LED2, and LED3. However, embodiments of the invention are not limited thereto.

The planarization layer PL may include an organic material. In an embodiment, for example, the planarization layer PL may include an organic material such as phenol resin, acrylic resin, polyimide resin, polyamide resin, siloxane resin, epoxy resin, etc. These can be used alone or in combination with each other.

The common electrode CME may be disposed on the planarization layer PL. The common electrode CME may be an electrode commonly disposed on the first to third light emitting diodes LED1, LED2, and LED3. In an embodiment, for example, the common electrode CME may include metal, alloy, metal nitride, conductive metal oxide, transparent conductive material, etc. These can be used alone or in combination with each other.

The passivation layer PVX may be disposed on the common electrode CME. The passivation layer PVX may include an inorganic material or an organic material. Examples of the inorganic material may include silicon oxide, silicon nitride, and silicon oxynitride. Examples of the organic material may include phenolic resin, polyacrylates resin, polyimides rein, polyamides resin, siloxane resin, and epoxy resin. These can be used alone or in combination with each other.

The micro lens array MLA may be disposed on the passivation layer PVX. The micro lens array MLA may refract light. Accordingly, the micro lens array MLA may converge light and may improve light use efficiency.

Referring to FIG. 4, in an embodiment, the micro lens array MLA may include a light blocking layer LSL, a hydrophobic pinning layer HPL, a micro lens ML, an adhesive layer ADL, a functional layer FL, and a hydrophobic coating layer HCL.

In an embodiment, the light blocking layer LSL may be disposed between the first to third light emitting diodes LED1, LED2, and LED3 and may block light. In an embodiment, the light blocking layer LSL may effectively prevent color mixing of lights emitted from the first to third light emitting diodes LED1, LED2, and LED3. In another embodiment, the light blocking layer LSL may be omitted.

The hydrophobic pinning layer HPL may be disposed on the light blocking layer LSL. The hydrophobic pinning layer HPL may include a hydrophobic material. In an embodiment, the hydrophobic pinning layer HPL may include or be formed of a material including fluorine. In an embodiment, for example, the hydrophobic pinning layer HPL may be formed of a commercially available fluorine-containing material such as Teflon™ or Cytop™. In another embodiment, the hydrophobic pinning layer HPL may include or be formed as a self-assembled monolayer (SAM). In an embodiment, for example, the hydrophobic pinning layer HPL may include octadecyltrichlorosilane, fluoroalkyltrichlorosilane, perfluoroalkyltriethoxysilane, etc. These can be used alone or in combination with each other.

In an embodiment, the hydrophobic pinning layer HPL may have a predetermined contact angle. In an embodiment, for example, the contact angle of the hydrophobic pinning layer HPL with respect to water may be in a range of about 100° to about 200°, and the contact angle of the hydrophobic pinning layer HPL with respect to the resin may be in a range of about 20° to about 100°. Accordingly, the shape of the micro lens ML may be controlled and fixed by the hydrophobic pinning layer HPL. In an embodiment, for example, the shape of the micro lens ML may be set based on the target focal length, anisotropy, birefringence, refractive index, chromatic aberration, curvature, etc. The contact angle of the hydrophobic pinning layer HPL may be set based on the shape of the micro lens ML.

The micro lens ML may be disposed on each of the above-described light emitting diodes and may overlap with each light emitting diodes. In an embodiment, for example, the micro lens ML may be disposed on the first light emitting diode LED1 and may overlap the first light emitting diode LED1. The micro lens ML may refract light. Accordingly, the micro lens ML may converge light and may improve light use efficiency.

In an embodiment, the micro lens ML may include resin. The resin used as the micro lens ML may be appropriately selected in consideration of the density, refractive index, curvature, etc. of the target micro lens ML. In an embodiment, for example, the resin used as the micro lens ML may include phenolic resin, polyacrylates resin, polyimides rein, polyamides resin, and siloxane resin. resin, epoxy resin, etc. These can be used alone or in combination with each other.

In an embodiment, the hydrophobic pinning layer HPL may be formed using the micro lens ML as a mask. Accordingly, as shown in FIG. 4, the boundary of the hydrophobic pinning layer HPL may be aligned with the boundary of the micro lens ML.

In an embodiment, the adhesive layer ADL may be disposed on the micro lens ML and may cover the micro lens ML and the hydrophobic pinning layer HPL. The adhesive layer ADL may adhere the micro lens ML and the functional layer FL to each other.

In an embodiment, the functional layer FL may be disposed on the adhesive layer ADL and may cover the adhesive layer ADL. The functional layer FL may improve surface wear resistance and may protect the micro lens ML to ensure reliability. In addition, the functional layer FL may secure an optimal refractive index together with the micro lens ML.

In an embodiment, the functional layer FL may include or be formed of a material to ensure the above-described wear resistance, reliability, and refractive index. In an embodiment, for example, the functional layer FL may include at least one selected from an organic material, an inorganic oxide, and a metal oxide. Examples of materials that can be used as the functional layer FL may include phenolic resin, polyacrylates resin, polyimides rein, polyamides resin, siloxane resin, epoxy resin, silicon oxide (SiOx), silicon nitride (SiNx), silicon carbide (SiCx), silicon oxynitride (SiOxNy), silicon oxycarbide (SiOxCy), aluminum oxide (Al₂O₃), titanium oxide (TiO₂), zinc oxide (ZnO), etc. These can be used alone or in combination with each other.

The hydrophobic coating layer HCL may be disposed on the functional layer FL and may cover the functional layer FL. The hydrophobic coating layer HCL may include a hydrophobic material. In an embodiment, the hydrophobic coating layer HCL may include a same material as the hydrophobic pinning layer HPL. In another embodiment, the hydrophobic coating layer HCL may include a different material from the hydrophobic pinning layer HPL.

In an embodiment, the hydrophobic coating layer HCL may include or be formed of a material including fluorine. In an embodiment, for example, the hydrophobic coating layer HCL may be formed of a commercially available fluorine-containing material such as Teflon™ or Cytop™. In another embodiment, the hydrophobic coating layer HCL may be formed as a self-assembled monolayer (SAM). In an embodiment, for example, the hydrophobic coating layer HCL may include octadecyltrichlorosilane, fluoroalkyltrichlorosilane, perfluoroalkyltriethoxysilane, etc. These can be used alone or in combination with each other.

In an embodiment, the hydrophobic coating layer HCL may have a predetermined contact angle. In an embodiment, for example, the contact angle of the hydrophobic coating layer HCL with respect to water may be in a range of about 100° to bout 200°, and the contact angle of the hydrophobic coating layer HCL with respect to the resin may be in a range of about 20° to about 100°. Accordingly, the friction coefficient of the hydrophobic coating layer HCL may be reduced and slip properties may be improved.

Referring to FIG. 5, in an embodiment, the first light emitting diode LED1 may be disposed between the first pixel electrode PE1 and the common electrode CME. In an embodiment, the first light emitting diode LED1 may include a connection layer CL, a first semiconductor layer SL1, an active layer MQW, a second semiconductor layer SL2, and a third semiconductor layer SL3.

The connection layer CL may be disposed on the first pixel electrode PE1. The connection layer CL may bond the first light emitting diode LED1 and the first pixel electrode PE1. The connection layer CL may serve to transmit an emission signal from the first pixel electrode PE1 to the first light emitting diode LED1. In an embodiment, the connection layer CL may be an ohmic connection electrode. In another embodiment, the connection layer CL may be a Schottky connection electrode.

In an embodiment, for example, the connection layer CL may include Au, Cu, Sn, Ag, Al, Ti, etc. These can be used alone or in combination with each other. In an embodiment, for example, the connection layer CL may include Sn—Ag—Cu alloy. However, embodiments of the invention are not limited thereto.

The first semiconductor layer SL1 may be disposed on the connection layer CL. In an embodiment, the first semiconductor layer SL1 may include a p-type semiconductor. In an embodiment, for example, the first semiconductor layer SL1 may include p-type doped AlGaInN, GaN, AlGaN, InGaN, AlN, InN, etc. These can be used alone or in combination with each other. The first semiconductor layer SL1 may be doped with a p-type dopant, and the p-type dopant may include Mg, Zn, Ca, Se, Ba, etc. These can be used alone or in combination with each other. In an embodiment, for example, the first semiconductor layer SL1 may include p-GaN doped with p-type Mg.

An electron blocking layer may be additionally disposed between the active layer MQW and the first semiconductor layer SL1. The electron blocking layer may be a layer to suppress or prevent electrons excessively from flowing into the active layer MQW. In an embodiment, for example, the electron blocking layer may include p-AlGaN doped with p-type Mg. In another embodiment, the electron blocking layer may be omitted.

The active layer MQW may be disposed on the first semiconductor layer SL1. The active layer MQW may generate light in response to an electrical signal applied thereto through the first semiconductor layer SL1 and the second semiconductor layer SL2.

The active layer MQW may include a material with a single or multiple quantum well structure. In an embodiment, for example, when the active layer MQW includes a material with a multi-quantum well structure, the active layer MQW may have a structure in which a plurality of well layers and barrier layers are alternately stacked. In this case, the well layers may include InGaN, and the barrier layer may include GaN or AlGaN. However, embodiments of the invention are not limited thereto.

In an embodiment, the active layer MQW may have a structure in which a type of semiconductor material with a large band gap energy and a semiconductor material with a small band gap energy are alternately stacked, and may include Group III to Group V semiconductor materials depending on the wavelength of the emitted light. In an embodiment, for example, when the active layer MQW includes indium (In), the color of the emitted light may vary depending on the In content. If the In content decreases, the wavelength band of the emitted light may shift to the red wavelength band, and if the In content increases, the wavelength band of the emitted light may shift to the blue wavelength band.

A superlattice layer may be additionally disposed between the active layer MQW and the second semiconductor layer SL2. The superlattice layer may be a layer for relieving stress between the active layer MQW and the second semiconductor layer SL2. In an embodiment, for example, the superlattice layer may include InGaN or GaN. In another embodiment, the superlattice layer may be omitted.

The second semiconductor layer SL2 may be disposed on the active layer MQW. In an embodiment, the second semiconductor layer SL2 may include an n-type semiconductor. In an embodiment, for example, the second semiconductor layer SL2 may include n-type doped AlGaInN, GaN, AlGaN, InGaN, AlN, InN, etc. These can be used alone or in combination with each other. The second semiconductor layer SL2 may be doped with an n-type dopant, and the n-type dopant may include Si, Ge, Sn, etc. These can be used alone or in combination with each other. In an embodiment, for example, the second semiconductor layer SL2 may include n-GaN doped with n-type Si.

The third semiconductor layer SL3 may be disposed on the second semiconductor layer SL2. In an embodiment, the third semiconductor layer SL3 may include an undoped semiconductor. The third semiconductor layer SL3 may include a same material as the second semiconductor layer SL2, but may include a material that is not doped with an n-type or p-type dopant. In an embodiment, for example, the third semiconductor layer SL3 may include undoped InAlGaN, GaN, AlGaN, InGaN, AlN, InN, etc. These can be used alone or in combination with each other. However, embodiments of the invention are not limited thereto.

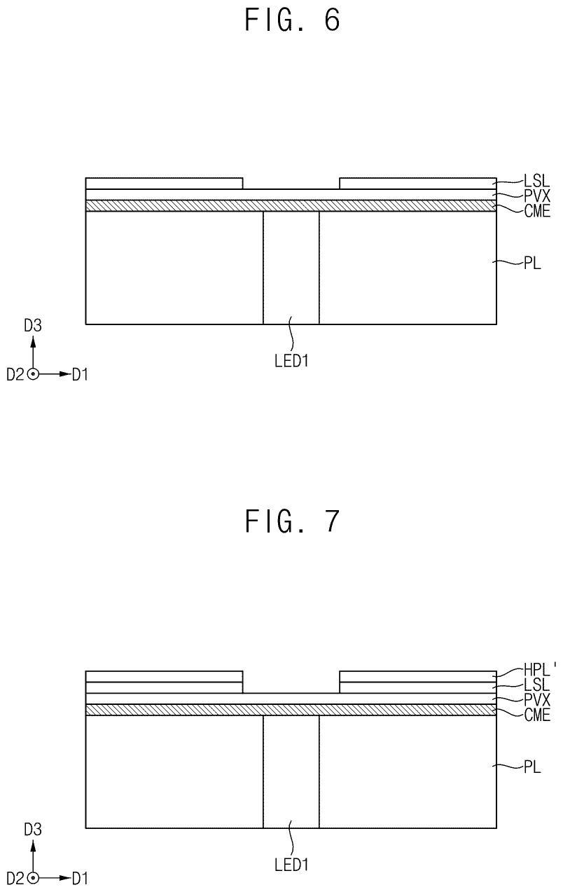

FIGS. 6 to 13 are cross-sectional views illustrating an embodiment of a method of manufacturing the display device of FIG. 1.

Referring to FIG. 6, in an embodiment of a method of manufacturing the display device, the light blocking layer LSL may be formed on the passivation layer PVX. The light blocking layer LSL may block light, and an opening that overlaps the first light emitting diode LED1 may be formed in the light blocking layer LSL.

Referring to FIG. 7, a preliminary hydrophobic pinning layer HPL′ may be formed on the light blocking layer LSL. The preliminary hydrophobic pinning layer HPL′ may cover the light blocking layer LSL, and an opening that overlaps the first light emitting diode LED1 may be formed in the preliminary hydrophobic fixed layer HPL′.

In an embodiment, the preliminary hydrophobic pinning layer HPL′ may be formed through a vapor deposition (e.g., chemical vapor deposition (CVD), physical vapor deposition (PVD), etc.) process.

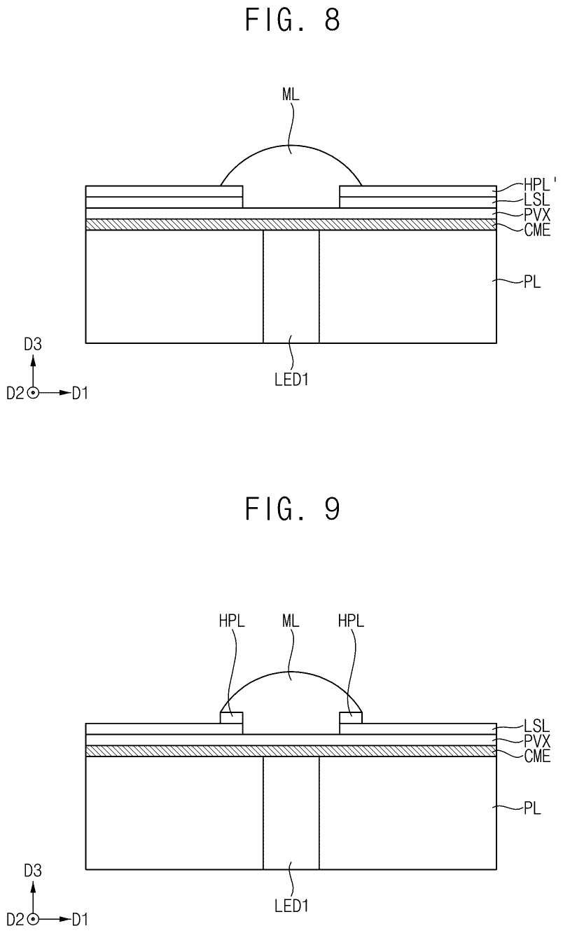

Referring to FIG. 8, a micro lens ML may be formed on the preliminary hydrophobic pinning layer HPL′. The micro lens ML may be formed in the opening to overlap the first light emitting diode LED1.

In an embodiment, the micro lens ML may include resin. In addition, the micro lens ML may be formed through a printing process (e.g., inkjet printing process, silk screen process, etc.). In such an embodiment, the micro lens ML may be formed and fixed (e.g., cured) into a target shape based on the contact angle of the preliminary hydrophobic pinning layer HPL′.

Referring to FIG. 9, the preliminary hydrophobic pinning layer HPL′ may be patterned to form the hydrophobic pinning layer HPL. In an embodiment, the preliminary hydrophobic pinning layer HPL′ may be removed by using the micro lens ML as a mask. In an embodiment, for example, a plasma treatment process or an ultraviolet radiation process may be performed on the preliminary hydrophobic pinning layer HPL′. Accordingly, the preliminary hydrophobic pinning layer HPL′ that does not overlap the micro lens ML may be removed. Accordingly, the boundary of the micro lens ML and the boundary of the hydrophobic pinning layer HPL may coincide or be aligned with each other. That is, the exterior side of the micro lens ML and the exterior side of the hydrophobic pinning layer HPL overlap each other in a plan view or when viewed in a third direction D3.

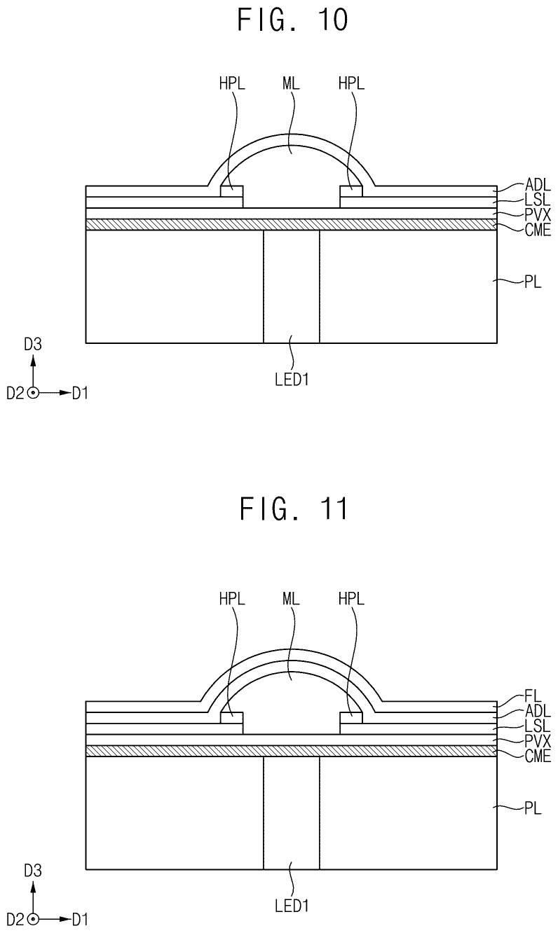

Referring to FIG. 10, the adhesive layer ADL may be formed on the micro lens ML. The adhesive layer ADL may include an adhesive material and may cover the micro lens ML, the hydrophobic pinning layer HPL, and the light blocking layer LSL.

In an embodiment, the adhesive layer ADL may be formed through a vapor deposition (e.g., chemical vapor deposition (CVD), physical vapor deposition (PVD), etc.) process.

Referring to FIG. 11, the functional layer FL may be formed on the adhesive layer ADL. For example, the functional layer FL may cover the adhesive layer ADL.

In an embodiment, the functional layer FL may be formed through a vapor deposition (e.g., chemical vapor deposition (CVD), physical vapor deposition (PVD), etc.) process.

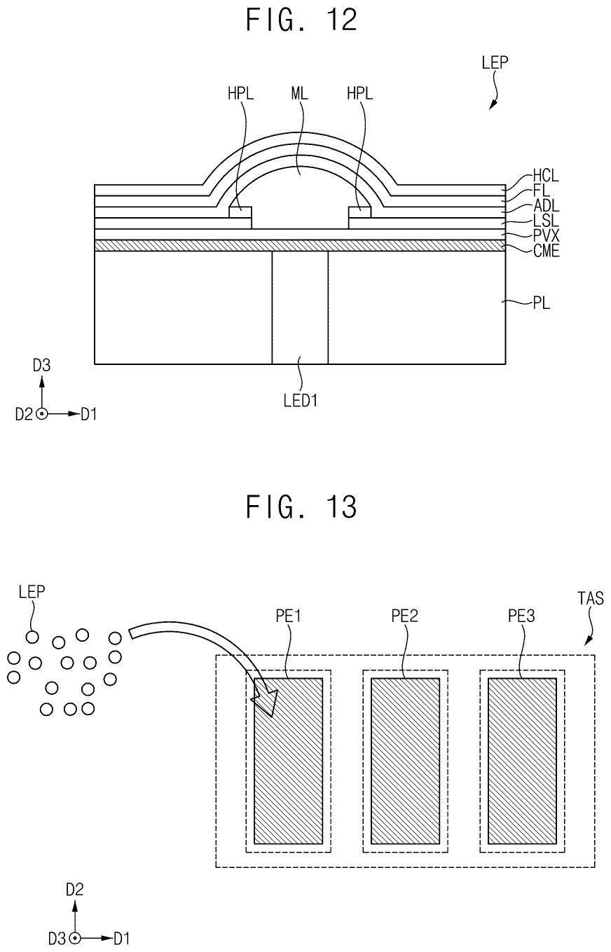

Referring to FIG. 12, the hydrophobic coating layer HCL may be formed on the functional layer FL. The hydrophobic coating layer HCL may entirely cover the functional layer FL.

In an embodiment, the hydrophobic coating layer HCL may be formed through a vapor deposition (e.g., chemical vapor deposition (CVD), physical vapor deposition (PVD), etc.) process.

Accordingly, a light emitting diode package LEP including the first light emitting diode LED1, the common electrode CME, the passivation layer PVX, the light blocking layer LSL, the hydrophobic pinning layer HPL, the micro lens ML, and the adhesive layer ADL, the functional layer FL, and the hydrophobic coating layer HCL may be formed.

Referring to FIG. 13, the light emitting diode package LEP may be transferred onto the TFT array substrate TAS.

In an embodiment, the light emitting diode package LEP may be transferred through a fluidic self-assembly (FSA) process. In an embodiment, for example, the light emitting diode package LEP may be arranged in a predetermined position on the first pixel electrode PE1 by electric/magnetic fields within the fluid.

The light emitting diode package LEP may include the micro lens ML, the functional layer FL, and the hydrophobic coating layer HCL. The micro lens ML may include or be formed of a resin, the functional layer FL may cover the micro lens ML, and the hydrophobic coating layer HCL may reduce the surface friction coefficient.

Accordingly, while the light emitting diode package LEP is transferred through the FSA process, fluid may not penetrate into the interior of the light emitting diode package LEP, the micro lens ML may be protected, and the light emitting diode package LEP may be smoothly aligned to the target position.

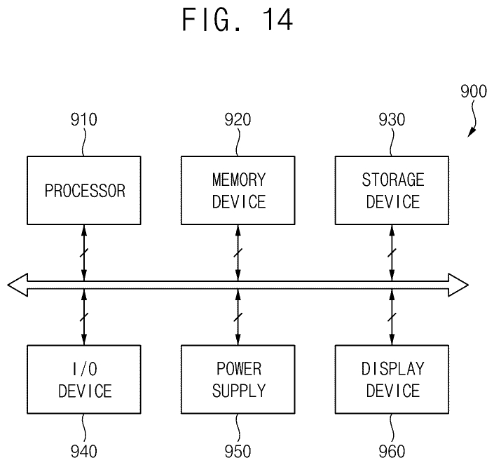

FIG. 14 is a block diagram illustrating an electronic device according to an embodiment.

Referring to FIG. 14, in an embodiment, an electronic device 900 may include a processor 910, a memory device 920, a storage device 930, an input/output (“I/O”) device 940, a power supply 950, and a display device 960. Here, the display device 960 may correspond to the display device DD of FIG. 1. The electronic device 900 may further include a plurality of ports for communicating with a video card, a sound card, a memory card, a universal serial bus (“USB”) device, or the like. In an embodiment, the electronic device 900 may be implemented as a television. In another embodiment, the electronic device 900 may be implemented as a smart phone. However, embodiments are not limited thereto, in another embodiment, the electronic device 900 may be implemented as a cellular phone, a video phone, a smart pad, a smart watch, a tablet personal computer (“PC”), a car navigation system, a computer monitor, a laptop, a head disposed (e.g., mounted) display (“HMD”), or the like.

The processor 910 may perform various computing functions. In an embodiment, the processor 910 may be a microprocessor, a central processing unit (“CPU”), an application processor (“AP”), or the like. The processor 910 may be coupled to other components via an address bus, a control bus, a data bus, or the like. In an embodiment, the processor 910 may be coupled to an extended bus such as a peripheral component interconnection (“PCI”) bus.

The memory device 920 may store data for operations of the electronic device 900. In an embodiment, the memory device 920 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, or the like, and/or at least one volatile memory device such as a dynamic random access memory (“DRAM”) device, a static random access memory (“SRAM”) device, a mobile DRAM device, or the like.

In an embodiment, the storage device 930 may include a solid state drive (“SSD”) device, a hard disk drive (“HDD”) device, a CD-ROM device, or the like. In an embodiment, the I/O device 940 may include an input device such as a keyboard, a keypad, a mouse device, a touchpad, a touch-screen, or the like, and an output device such as a printer, a speaker, or the like.

The power supply 950 may provide power for operations of the electronic device 900. The power supply 950 may provide power to the display device 960. The display device 960 may be coupled to other components via the buses or other communication links. In an embodiment, the display device 960 may be included in the I/O device 940.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a light emitting diode disposed on a thin-film transistor array substrate;
a micro lens disposed on the light emitting diode, overlapping the light emitting diode, and including a resin; and
a hydrophobic coating layer disposed on the micro lens and covering the micro lens.

2. The display device of claim 1, wherein a contact angle of the hydrophobic coating layer with respect to water is in a range of about 100° to about 200°, and
wherein a contact angle of the hydrophobic coating layer with respect to the resin is in a range of about 20° to about 100°.

3. The display device of claim 1, further comprising:
an adhesive layer disposed between the micro lens and the hydrophobic coating layer.

4. The display device of claim 1, further comprising:
a functional layer disposed between the micro lens and the hydrophobic coating layer.

5. The display device of claim 4, wherein the functional layer includes an organic material.

6. The display device of claim 4, wherein the functional layer includes at least one selected from an inorganic oxide and a metal oxide.

7. The display device of claim 1, further comprising:
a hydrophobic pinning layer disposed between the light emitting diode and the micro lens.

8. The display device of claim 7, wherein a boundary of the hydrophobic pinning layer is aligned with a boundary of the micro lens in a plan view.

9. The display device of claim 1, wherein the light emitting diode includes:
a first semiconductor layer;
an active layer disposed on the first semiconductor layer; and
a second semiconductor layer disposed on the active layer.

10. The display device of claim 1, further comprising:
a pixel electrode disposed under the light emitting diode; and
a common electrode disposed on the light emitting diode,
wherein the light emitting diode is arranged perpendicularly to the pixel electrode.

11. A method of manufacturing a display device, the method comprising:
forming a light emitting diode package including a light emitting diode; and
transferring the light emitting diode package onto a thin-film transistor array substrate,
wherein the forming the light emitting diode package includes:
forming a micro lens on the light emitting diode, wherein the micro lens overlaps the light emitting diode and includes a resin; and
forming a hydrophobic coating layer on the micro lens, wherein the hydrophobic coating layer covers the micro lens.

12. The method of claim 11, wherein the forming the light emitting diode package further includes:
forming an adhesive layer between the micro lens and the hydrophobic coating layer.

13. The method of claim 11, wherein the forming the light emitting diode package further includes:
forming a functional layer between the micro lens and the hydrophobic coating layer.

14. The method of claim 11, wherein the forming the light emitting diode package further includes:
forming a hydrophobic pinning layer between the micro lens and the hydrophobic coating layer.

15. The method of claim 14, wherein the forming the hydrophobic pinning layer includes:
forming a preliminary hydrophobic pinning layer; and
removing a portion of the preliminary hydrophobic pinning layer in a way such that a boundary of the preliminary hydrophobic pinning layer is aligned with a boundary of the micro lens in a plan view.

16. The method of claim 11, wherein the light emitting diode package is transferred through a fluidic self-assembly process.

17. An electronic device comprising:
a display device; and
a power supply configured to provide power to the display device,
wherein the display device comprises:
a light emitting diode disposed on a thin-film transistor array substrate;
a micro lens disposed on the light emitting diode, overlapping the light emitting diode, and including a resin; and
a hydrophobic coating layer disposed on the micro lens and covering the micro lens.
